(19) United States
(12) Patent Application Publication
(10) Pub. No.: US 2006/0199371 A1
(43) Pub. Date: Sep. 7, 2006

(54) SEMICONDUCTOR DEVICES PASSIVATION FILM

(75) Inventors: Hideki Mizuhara, Aichi-ken (JP); Yasunori Inoue, Gifu-ken (JP); Hiroyuki Watanabe, Aichi-ken (JP); Masaki Hirase, Kanagawa-Ken (JP); Kaori Misawa, Gifu-ken (JP); Hiroyuki Aoe, Kyoto (JP); Kimihide Saito, Gunma-ken (JP); Hiroyasu Ishihara, Gifu-ken (JP)

Correspondence Address: SHERIDAN ROSS PC, 1560 BROADWAY, SUITE 1200, DENVER, CO, 80202, US

(73) Assignee: SANYO ELECTRIC CO., LTD., Osaka (JP)

(21) Appl. No.: 11/419,450

(22) Filed: May 19, 2006

Related U.S. Application Data
(62) Division of application No. 09/037,674, filed on Mar. 9, 1998.
Application No. 09/037,674 is a continuation-in-part of application No. 08/949,283, filed on Oct. 21, 1997, now Pat. No. 6,214,749.
Application No. 08/949,283 is a continuation of application No. 08/528,123, filed on Sep. 14, 1995, now abandoned.

(30) Foreign Application Priority Data
Mar. 17, 1997 (JP) 9-063405

(51) Int. Cl. H01L 21/4763

(52) U.S. Cl. 438/624

(57) ABSTRACT

A semiconductor device includes a substrate and wirings located on the substrate. A passivation film including a first insulating film containing an impurity is located on the wirings. The first insulating film is formed from silicon oxide film materials containing greater than one percent carbon.

### CROSS-REFERENCE TO RELATED APPLICATIONS

This application is a Divisional of pending U.S. patent application Ser. No. 09/037,674 filed on Mar. 9, 1998, entitled “Semiconductor Devices Passivation Film” which in turn is a Continuation-In-Part of pending U.S. patent application Ser. No. 08/949,283 filed on Oct. 21, 1997, now U.S. Pat. No. 6,214,749 issued on Apr. 10, 2001, entitled “Process for Producing Semiconductor Devices and Semiconductor Devices Produced thereby” which in turn is a Continuation of U.S. patent application Ser. No. 08/528,123 filed on Sep. 14, 1995, entitled “Process for Producing Semiconductor Devices and Semiconductor Devices Produced thereby”, now abandoned.

### BACKGROUND OF THE INVENTION

The present invention relates generally to a semiconductor device and a process for producing the same. Particularly, the present invention relates to the structure of a passivation film for insulating and protecting wirings and a technique of forming the passivation film.

In order to stabilize performance of semiconductor devices, a passivation film for insulating and protecting wirings is formed conventionally on the surface of each device.

Generally, the passivation film is an insulating film formed by means of thermal CVD or plasma CVD. Particularly, silicon nitride films formed by means of plasma CVD are frequently employed because of their excellent moisture resistance. However, silicon nitride films are not fully resistant to moisture but permit permeation of very small amounts of moisture.

Japanese Unexamined Patent Publication No. 6-53210 discloses a technique of achieving absorption and dispersion of moisture permeating the silicon nitride film by forming a PSG (phospho-silicate glass) film under the silicon nitride film. The publication also discloses forming another silicon nitride film under the PSG film to enhance moisture resistance. However, there still remains the apprehension that the moisture will affect wirings even if moisture is absorbed and dispersed in the PSG film.

It is an objective of the present invention to provide a semiconductor device having a passivation film with excellent moisture resistance, as well as, a process for producing the same.

### SUMMARY OF THE INVENTION

Briefly stated, the present invention provides a semiconductor device including a semiconductor substrate, wirings located on the semiconductor substrate, and a passivation film, located on the wirings, including a first insulating film which contains an impurity. The first insulating film is formed from silicon oxide film materials containing over 1% carbon.

The present invention provides a semiconductor device including a semiconductor substrate, wirings located on the semiconductor substrate, and a passivation film, located on the wirings, including a first insulating film which contains an impurity. The first insulating film includes an inorganic SOG (Spin-on-Glass).

The present invention provides a semiconductor device including a semiconductor substrate, wirings located on the semiconductor substrate, and a passivation film located on the wirings, including a first insulating film and a second insulating film. The first insulating film contains an impurity and is formed from silicon oxide film materials containing over 1% carbon. The second insulating film is located on at least one of an upper side and a lower side of the first insulating film.

The present invention provides a semiconductor device including a semiconductor substrate, wirings located on the semiconductor substrate, and a passivation film located on the wirings, including a first insulating film and a second insulating film. The first insulating film includes an inorganic SOG (Spin-on-Glass) film containing an impurity. The second insulating film is located on at least one of an upper vide and a lower aide of the first insulating film.

The present invention provides a method of fabricating a semiconductor device including the steps of: forming wirings on a semiconductor substrate; forming a passivation film including a first insulating film on the wirings; and introducing an impurity into the first insulating film.

Other aspects and advantages of the invention will become apparent from the following description, taken in conjunction with the accompanying drawings, illustrating byway of example the principles of the invention.

### BRIEF DESCRIPTION OF THE DRAWINGS

The invention, together with the objects and advantages thereof, may best be understood by reference to the following description of the presently preferred embodiments taken in conjunction with the accompanying drawings in which:

FIGS. 1 through 10 are cross-sectional views showing a process for producing a semiconductor device according to a first embodiment of the present invention;

FIGS. 11 through 20 are cross-sectional views showing a process for producing a semiconductor device according to a second embodiment of the present invention;

FIGS. 21 through 25 are characteristic charts for explaining the embodiments of the present invention;

FIG. 26 is a graph showing characteristic curves of SOG films; and

FIGS. 27 and 28 are graphs showing characteristic curves of various types of SOG films.

### DETAILED DESCRIPTION OF THE PREFERRED EMBODIMENTS

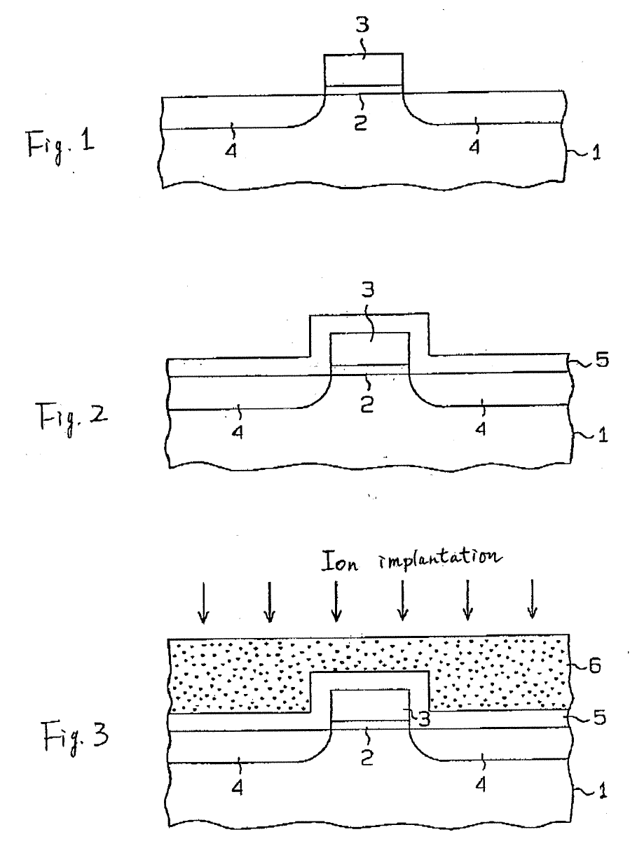

A process for producing a semiconductor device according to a first embodiment of the invention will be described referring to FIGS. 1 to 10.

In Step 1 shown in FIG. 1, a gate insulating film 2 (film thickness: about 10 nm) and a gate electrode 3 (film thickness: about 200 nm) are formed on a [100] p-type (or n-type) single crystal silicon substrate 1. Then, the substrate 1 is doped with an n-type (or p-type) impurity by means of ion implantation utilizing the gate insulating film 2 and gate electrode 3 as a mask to form source and drain regions 4 in self alignment to form an MOS transistor.

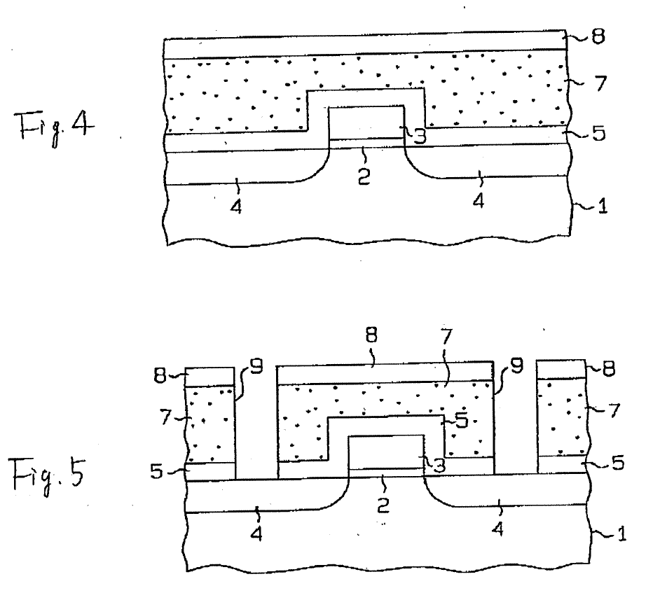

Next, in Step 2 shown in FIG. 2, a silicon oxide film 5 (film thickness: about 500 nm) is formed over the entire surface of the formed MOS device using a plasma CVD method. The gas employed in the plasma CVD method is preferably a mixed gas of, for example, monosilane and nitrogen suboxide (SiH₄+N₂O) monosilane and oxygen (SiH₄+O₂) or TEOS (tetra-ethoxy-silane) and oxygen (TEOS+O₂). The silicon oxide film 5 is formed at a temperature of 300 to 900° C.

In Step 3 shown in FIG. 3, an organic SOG (Spin On Glass) film 6 is formed on the silicon oxide film 5. The silicon-containing compound of the organic SOG film 6 has a composition of [CH₃Si (OH) 3] and a film thickness of about 400 nm. Referring to the method of forming the film 6, a solution of the silicon-containing compound in an alcoholic solvent (e.g., IPA (isopropyl alcohol)+acetone) is first dropped onto the substrate 1, and then the substrate 1 is rotated at about 5400 rpm for about 20 seconds to form a film of the solution on the substrate 1. In this process, the film 6 is formed to compensate for steps present on the substrate 1. That is, the solution is preferably applied thick in recesses of the substrate 1 and thin at protrusions thereof. Thus, the surface of the alcoholic solution film is planarized.

Next, the thus treated substrate 1 is heat-treated successively at 100° C. for one minute, at 200° C. for one minute, at 300° C. for one minute, at 22° C. for one minute and at 300° C. for 30 minutes in a nitrogen atmosphere to evaporate the alcoholic solvent and also to promote a polymerization reaction of the silicon-containing compound, forming the organic SOG film 6 having a flat surface. The organic SOG film 6 is an organic insulating film that contains over 1% carbon.

The organic SOC film 6 is then doped with argon ions (Ar⁺) by means of ion implantation to achieve decomposition of the organic components, as well as, reduction of the water and hydroxyl groups contained in the film 6. The doping treatment is carried out with an acceleration energy of 140 keV and a dose of about 1×10¹⁵ ions/cm². As a result, the organic SOG film 6 is converted to an SOG film, hereinafter referred to as the modified SOG film 7 containing only small amounts of water and hydroxyl groups and no organic component. It should be noted here that the argon ions correspond to the impurity having a kinetic energy.

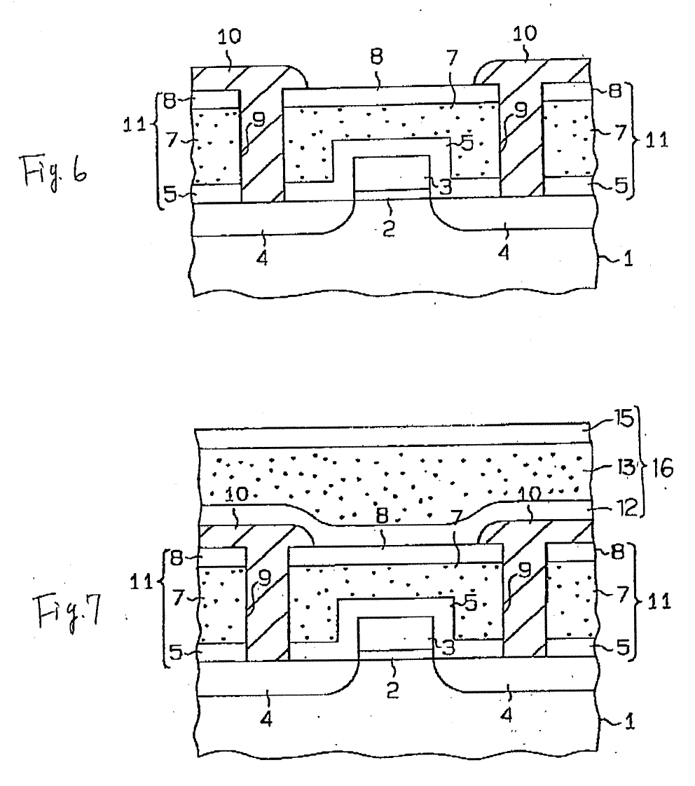

In Step 4 shown in FIG. 4, a silicon oxide film 8 (film thickness: about 200 nm) is formed on the modified SOG film 7 using a plasma CVD method. The silicon oxide film 8 is formed under the same conditions as the silicon oxide film 5 is formed. In Step 5 shown in FIG. 5, via holes 9 are formed through the films 5, 7 and 8 present on the source/drain regions 4 by anisotropic etching such as by employing a mixed gas of carbon tetrafluoride and hydrogen as an etching gas.

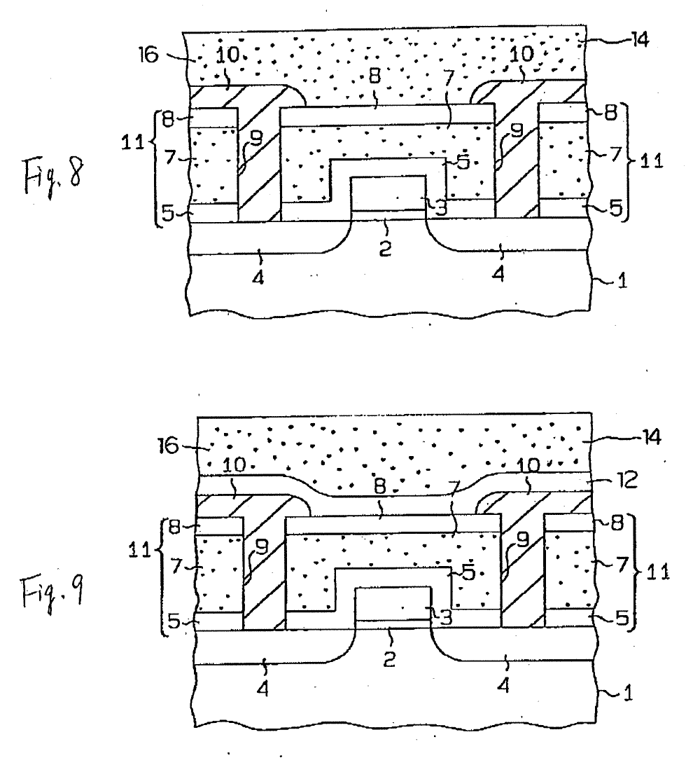

In Step 6 shown in FIG. 6, an aluminum film is formed on the silicon oxide film 8 including the bores of the via holes 9 by sputtering. The aluminum film is then removed partly by anisotropic etching until the silicon oxide film 8 is partly exposed to form source and drain electrodes (source and drain wirings) 10 in a desired pattern.

In Step 7 shown in FIG. 7, a silicon oxide film 12 (film thickness: about 200 nm) is formed over the entire surface of the device. Subsequently, an organic SOO film 13 is formed on the silicon oxide film 12, followed by implantation of argon ions to the organic SOG film 13 to form a modified SOG film 14 (film thickness: about 400 nm). The organic SOG film 13 and the modified SOG film 14 are preferably formed in the same manner as the organic SOG film 6 and the modified SOG film 7.

Next, a silicon oxide film 15 (film thickness: about 200 to about 400 nm) is formed on the modified SOG film 14. The silicon oxide films 12 and 15 are preferably formed in the same manner as the silicon oxide film 5 is formed in Step 2. The silicon oxide film 12, the modified SOG film 14 and the silicon oxide film 15 comprises a passivation film 16. The passivation film 16 insulates and protects the device, particularly the source and drain electrodes 10. The passivation film 16 according to the present invention has a sandwich structure in which the modified SOG film 14 is sandwiched between the silicon oxide films 12 and 15. Accordingly, the passivation film 16 has high insulating properties and high mechanical strength.

Particularly, the insulating effect exhibited by the passivation film 16 is enhanced by the presence of the silicon oxide film 12. Furthermore, the silicon oxide film 12 exhibits better adhesion to wirings than to the modified SOG film 14, so that adhesion of the passivation film as a whole is improved. The presence of the silicon oxide film 15 enhances the moisture sealing effect of the passivation film 16. Further, the modified SOG film 14 has excellent step-covering properties, so that even narrow gaps between the wirings are fully embedded with the film 14. In addition, the modified 80 SOG film 14 has excellent evenness, it facilitates formation of the silicon oxide film 15. The silicon oxide films 12 and 15 also have good step-covering properties, so that narrow gaps present between the wirings are covered with the film 12 or 15 easily.

Since the modified SOG film 14 hardly contains moisture and hydroxyl groups and contains no organic component, the modified SOG film 14 alone may constitute the passivation film 16, as shown in FIG. 8. In this case, the procedures of forming the silicon oxide films 12 and 15 are omitted.

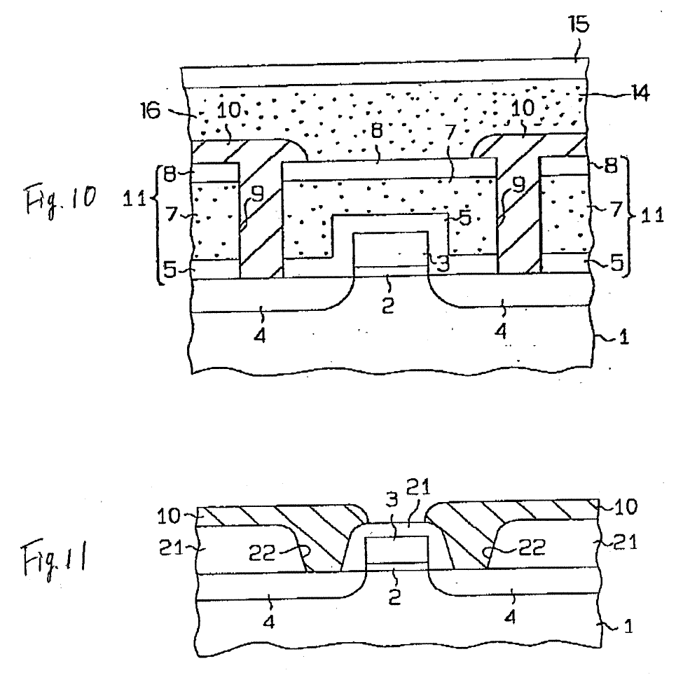

In the case where the organic SOG film 13 fails to be fully modified by ion implantation or the silicon oxide film 12 or 15 is desired to be omitted, the passivation film 16 may be formed having no silicon oxide film 15, as shown in FIG. 9, or having no silicon oxide film 12, as shown in FIG. 10.

The first embodiment employs the sandwich structure in which the modified SOG film 7 is sandwiched between the silicon oxide films 5 and 8, which enhances the insulating properties and mechanical strength of the layer insulating film 11 as a whole. Further, since the modified SOG film 7 contains no organic component, the etching treatment for forming the via holes 9 is carried out in a mixed gas atmosphere of carbon tetrafluoride and hydrogen. Accordingly, even if a photoresist is employed as an etching mask, the photoresist is not attacked, nor is the modified SOG film 7 masked with the photoresist etched. Thus, fine via holes 9 are formed accurately.

Since the modified SOG film 7 contains no organic component, the modified SOG film 7 and the silicon oxide films 5 and 8 may be etched at the same etching rate. In addition, the modified SOG film 7 undergoes no shrinkage during ashing treatment for removing the photoresist etching mask. Accordingly, the modified SOG film 7 undergoes neither cracking nor formation of recesses when the via holes 9 are formed. Thus, the aluminum film can be embedded fully in the via holes 9 to secure excellent contact between the source and drain electrodes 10 and the source and drain regions 4 respectively.

Since the modified SOG film 7 contains very small amounts of moisture and hydroxyl groups and no organic component, either the silicon oxide film 5 or the silicon oxide film 8 or both may be omitted to allow the layer insulating film 11 to have a single layer structure consisting of the modified SOG film 7 only or a two-layer structure consisting of the modified SOG film 7 and the silicon oxide film 5 or 8.

Next, a process for producing a semiconductor device according to a second embodiment of the invention will be described referring to FIGS. 11 to 20. It should be rioted here that like and same components as in the first embodiment are affixed with the same reference numbers respectively and detailed description of them will be omitted.

In Step (1) shown in FIG. 11, on a p-type (or n-type) single crystal silicon substrate 1 are formed a gate insulating film 2, a gate electrode 3 and source and drain regions 4 to complete an MOS transistor. An interlayer insulating film 21 is then formed over the entire surface of the device, and contact holes 22 are defined through the interlayer insulating film 21 over the source and drain regions 4. Subsequently, an aluminum film is deposited by means of sputtering over the entire surface of the device including the bores of the contact holes 22, and the aluminum film is subjected to anisotropic etching to form source and drain electrodes (source and drain wiring) 10 having desired patterns.

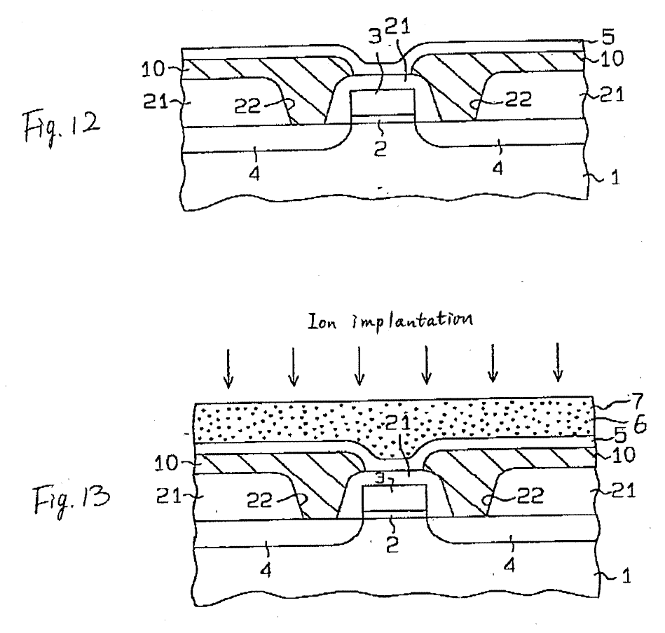

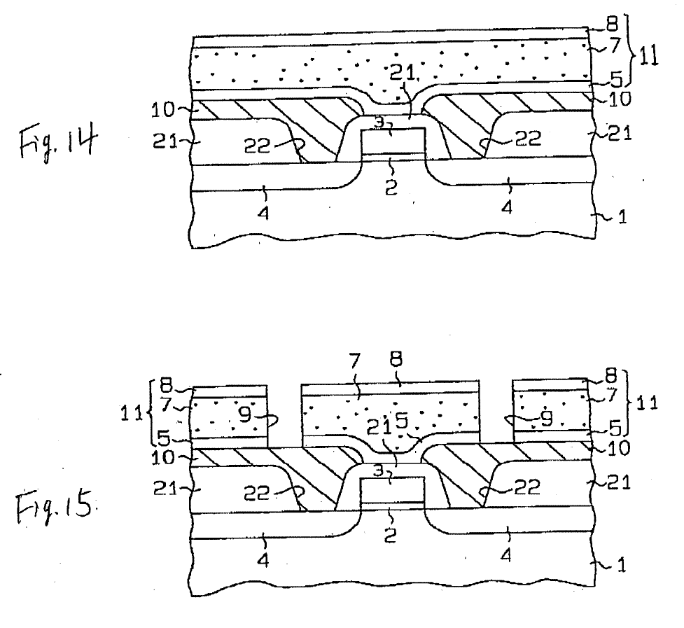

In Step (2) shown in FIG. 12, a silicon oxide film 5 is formed over the entire surface of the device. In Step (3) shown in FIG. 13, an organic SOG film 6 is formed on the silicon oxide film 5, followed by ion implantation to convert the organic SOG film 6 into a modified SOG film 7.

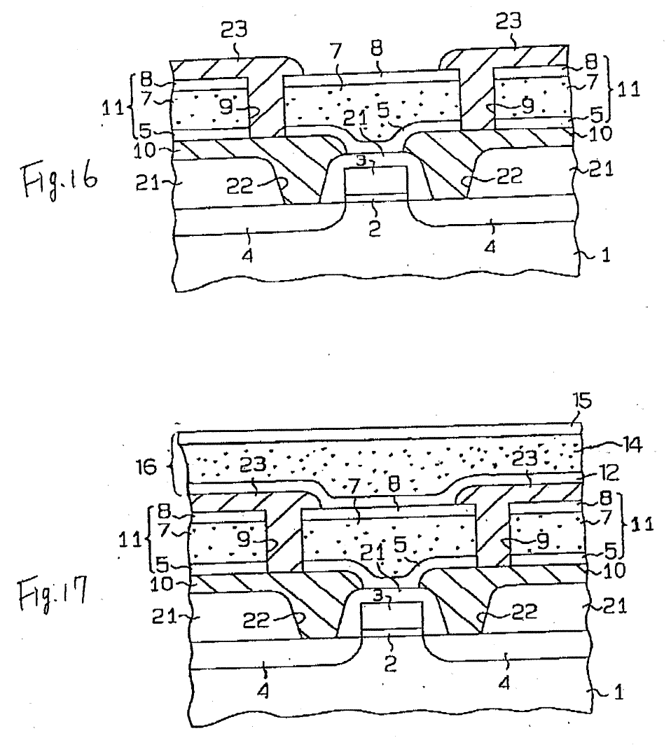

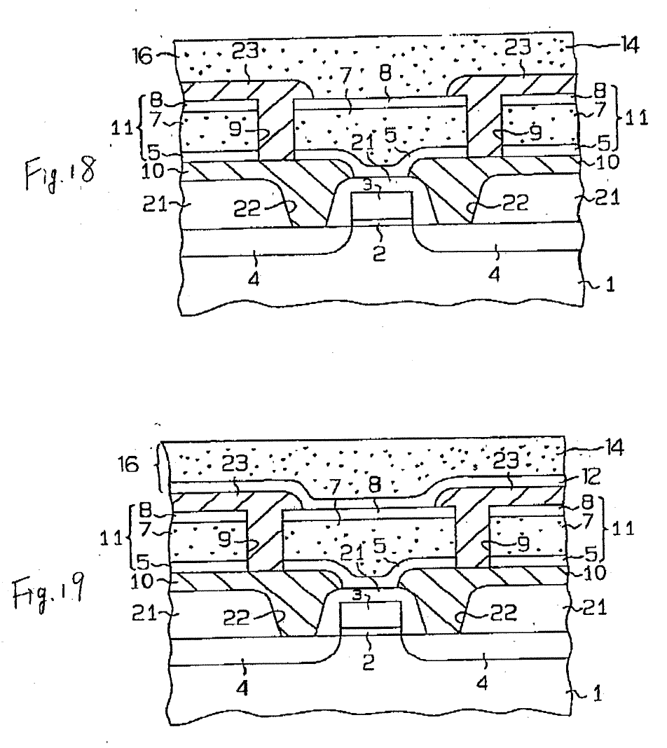

In Step (4) shown in FIG. 14, a silicon oxide film 8 is formed on the modified SOG film 7. The films 5, 7, 8 form a layer insulating film 11. In Step (5) shown in FIG. 15, the device is subjected to anisotropic etching, preferably using a mixed gas of carbon tetrafluoride and hydrogen as an etching gas to form via holes 9 through the films 5, 7 and 8 present on the source and drain areas 4. In step (6) shown in FIG. 16, aluminum is deposited over the entire surface of the device including the bores of the via holes 9 by means of sputtering, and the resulting aluminum film is then subjected to anisotropic etching to form wirings 23 in a desired pattern.

As described above, according to the second embodiment, the wirings 23 are formed on the source and drain wirings 10 via the layer insulating film 11. In this case again, the same actions and effects as in the first embodiment can be exhibited without affecting the MOS transistor and source and drain wirings 10.

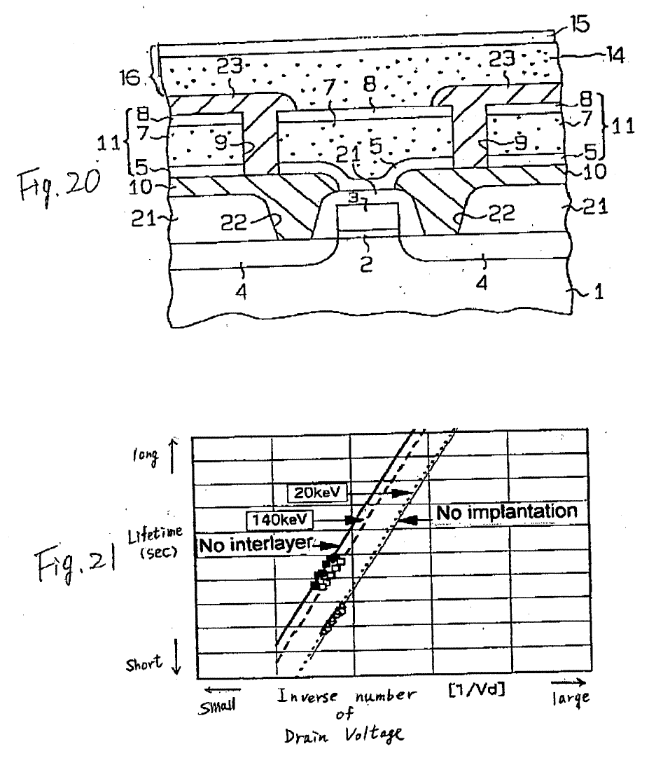

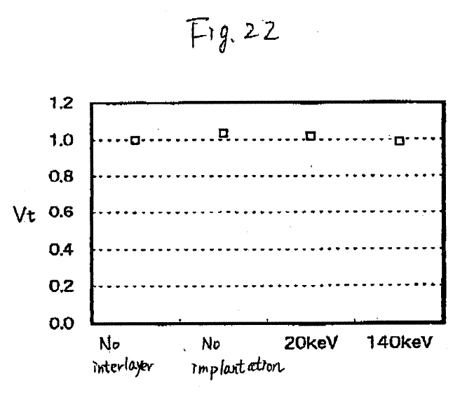

In Step (7) shown in FIG. 17, a passivation film 16 having a sandwich structure, comprising a silicon oxide film 12, a modified SOG film 14 and a silicon oxide film 15, is formed over the entire surface of the device in the same manner as in Step 7 of the first embodiment. The passivation film 16 may have a single layer structure consisting of the modified SOG film 14 only (see FIG. 18) or a two-layer structure consisting of the silicon oxide film 12 and the modified SOG film 14 (see FIG. 19) or of the silicon oxide film 15 and the modified SOG film 14 (see FIG. 20), like in the first embodiment, shown in FIGS. 8 to 10.

FIGS. 21 and 22 show results of various tests carried out employing a test device fabricated by forming an interlayer insulating film consisting of a silicon oxide film 8/an organic SOG film 6 (modified SOG film 7)/a silicon oxide film 5 on an NMOS transistor as shown in the first and second embodiments.

FIG. 21 shows drain voltage dependency of the hot carrier life in an NMOS transistor. The hot carrier life referred to here means the time elapsed until the mutual conductance Gm is deteriorated to a certain level and is a parameter showing the life of transistor. As shown in FIG. 21, the transistor employing a modified SOG film 7, particularly with the acceleration energy of 140 keV, has a hot carrier life of about twice that of a transistor employing an unimplanted organic SOG film.

FIGS. 22 and 23 show threshold values Vt measured before and after an acceleration test, respectively. In the acceleration test, a voltage of 5 V is continuously applied to the transistor of the test device at a temperature of 200° C. for 2 hours. FIG. 22 shows the threshold value Vt measured before the acceleration test; while FIG. 23 shows amount of change in the threshold value Vt after the acceleration teat. As shown in FIG. 22, before the acceleration test, both the transistor having the unimplanted organic SOG film and the transistor having the modified SOG film 7 showed no substantial difference in their threshold values.

However, as shown in FIG. 23, in the case where the unimplanted organic SOG film is employed, the threshold value Vt changes greatly after the test. On the other hand, in the case where the modified SOG film 7 (particularly with an acceleration energy of 140 keV) is employed, there is observed substantially no change in the threshold value Vt irrespective of the gate length. These results show that the threshold value characteristics of the MOS transistor having the modified SOG film 7 can be stabilized for a long time period.

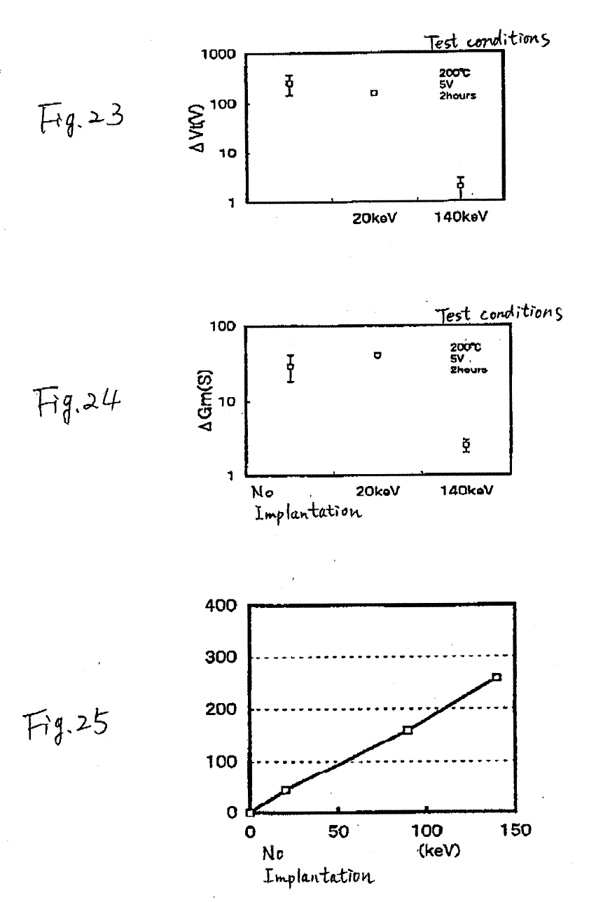

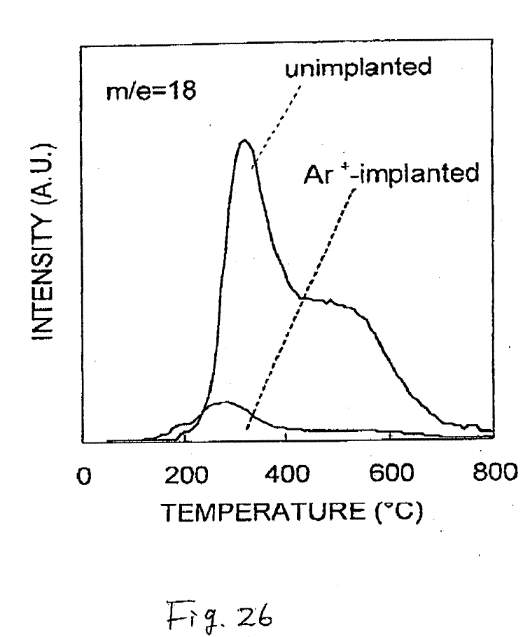

FIG. 24 shows the amount of change in the mutual conductance Gm of each transistor determined by measuring it before and after the acceleration test like in FIG. 23. In the case of a transistor employing an unimplanted organic SOG film, the Gm changed greatly after the test. On the other hand, in the case where the modified SOG film 7 (particularly with an acceleration energy of 140 keV) is employed, there is observed substantially no change in Gm irrespective of the gate length. These results show that the Gm of the MOS transistor can be stabilized for a long time period.

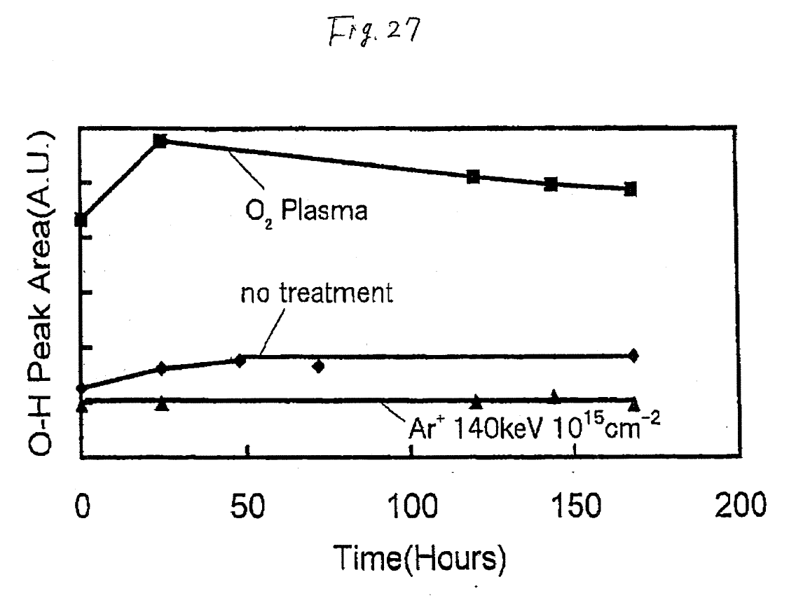

In FIGS. 21 to 24, in the case where the modified SOG film 7 formed with an acceleration energy of 20 keV, very small improving effects are shown compared with the case of the film formed with an acceleration energy of 140 keV. This may be because, as shown in FIG. 25, the acceleration energy (implantation energy) and the depth of modification in the organic SOG film have a substantially positive correlation, and in the case of the film modified with an acceleration energy of 20 keV, only the surface layer (about 50 nm) of the organic SOG film 6 is modified.

The unimplanted organic SOG film 6 (13) and the Ar⁺ implanted modified SOG film 7 were heat-treated in a nitrogen atmosphere for 30 minutes and evaluated by means of TDS (Thermal Desorption Spectroscopy), and the results are shown in FIG. 26. The ion implantation was carried out under the following conditions: dose: 1×10⁵ atoms/cm²; acceleration energy: 140 keV.

FIG. 26 represents a quantity of dissociation of H₂O (m/e=18). As shown in FIG. 26, it can be understood that dissociation of H₂O (m/e=18) is small in the modified SOG film 7 (14). This indicates that moisture and hydroxyl groups contained in the organic SOG film 6 (13) are decreased by forming the modified SOG film 7 (14) as a result of injecting ions into the organic SOG film 6 (13).

FIG. 27 shows a no-treatment organic SOG film 6 (13), an O₂, plasma organic SOG film 6 (13) having undergone oxygen plasma exposure and a modified (Ar⁺) SOG film 7(14) left to stand in a clean room under atmospheric conditions to examine hygroscopicity of the organic SOG films 6(13) and the modified SOG film 7(14). The water content of the film is indicated by the integrated intensity of the absorption (around 3500 cm⁻¹) attributed to the O-H group in the IR absorption spectrum by means of an FT-IR method (Fourier Transform Infrared Spectroscopy). The ion implantation was carried out under the following conditions: acceleration energy: 140 keV; dose: 1×10¹⁵ atoms/cm²

It can be understood that, when the organic film 6(13) was exposed to oxygen plasma, the water content increased not only immediately after the treatment but also after one day. Meanwhile, in the modified film 7(14), the water content did not increase immediately after the treatment, and the increase in the water content is smaller than the organic film 6(13) even if it was left to stand under atmospheric condition in a clean room. Further, the modified film 7(14) has hygroscopicity lower than the organic film 6(13).

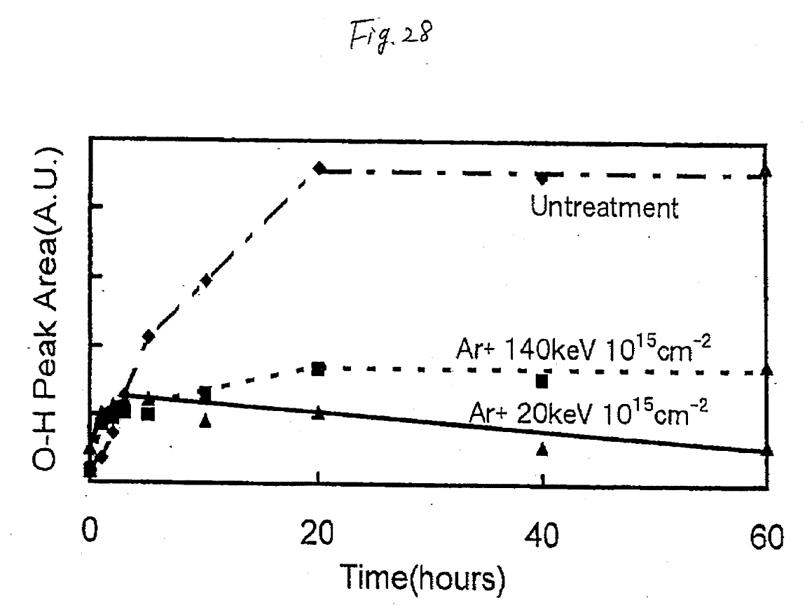

The modified SOG film 7(14) and the organic SOG film 6(13) were subjected to a pressure cooker test (PCT) to examine water permeability of the film 7, and the results are shown in FIG. 28. This test is a humidifying test and was carried out at 120° C. under 2 atm. saturated vapor pressure atmosphere. Integrated intensity of the absorption peak (around 3500 cm⁻¹) attributed to the O-H bond in the organic SOG film 6(13) was determined by means of FT-IR and plotted with respect to the PCT time.

A sample modified only on the surface of the organic SOG film 6 by means of ion implantation (Ar⁺ 20 keV) was prepared by implanting argon to the organic SOG film 6, which was compared with an entirely modified organic SOG film 6 (Ar⁺ 140 keV) and an unmodified sample (an untreatment organic SOG film 6(13)) to obtain the following results:

(1) When the unmodified organic SOG film 6 (13) was subjected to PCT, an absorbance around 3500 cm⁻¹ attributed to O—H showed a steep increase.

(2) In the modified SOG film 7(14), an increase in the absorbance around 3500 cm⁻¹ attributed to O—H is small. The surface-modified film also showed a similar level of increase to that of the entirely modified film.

From these results, it can be considered that a layer which inhibits permeation of water was formed by the ion implantation.

The present invention is not to be limited to the foregoing embodiments, and similar actions and effects maybe exhibited if embodied as follows.

The silicon oxide films 5, 8, 12 and 15 may be formed by a method other than the plasma CVD method, for example, atmospheric CVD method, vacuum CVD method, ECR plasma CVD method, optical pumping CVD method, TEOS-CVD method and PVD method. The gas used in the atmospheric CVD method is preferably monosilane and oxygen (SiH₄+O₂), and the films are formed at a temperature of about 400° C. or lower. Meanwhile, the gas used in the vacuum CVD method is preferably monosilane and nitrogen suboxide (SiH₄+N₂O), and the films are formed at a temperature of about 900° C. or lower.

The silicon oxide films 5, 8, 12 and 15 may be replaced with other insulating films having high mechanical strength in addition to the property of blocking water and hydroxyl groups, such as silicon nitride film, silicon oxynitride film and silicate glass film. Such insulating film may be formed according to any method including CVD and PVD.

Particularly, when silicon nitride films are employed in place of the silicon oxide film 12 and the silicon oxide film 15, they prevent devices from being affected by alkali metals, since they do not allow permeation of alkali metals such as Na and K. Further, when silicon oxynitride films are employed in place of the silicon oxide film 12 and the silicon oxide film 15, the same actions and effects as those of the silicon nitride film can be exhibited, since the silicon oxynitride films do not allow permeation of alkali metals such as Na and K. In addition, the silicon oxynitride film exhibit high effects of preventing deterioration of device performance attributed to stress and deterioration of wiring reliability compared with the silicon nitride films.

The source and drain electrodes 10 and the wiring 23 may be formed using conductive materials other than aluminum, such as copper, gold, silver, silicide, doped polysilicones, titanium nitride (TiN) and alloys including tungsten titanium (TiW), or a laminated structure of such materials.

The modified SOG films 7 and 14 may be subjected to thermal treatment. In this case, the number of dangling bonds in the modified SOG films 7 and 14 is reduced, so that not only hygroscopicity but also water permeability of the film 7 can be reduced further.

Each of the organic SOG films 6 and 13 may be replaced with an inorganic SOG film, and the inorganic SOG film may be subjected to ion implantation. In this case, the water and hydroxyl groups contained in the inorganic SOG film can be reduced.

While argon ion is employed as the ion to be implanted to the organic SOG films 6 and 13 in the foregoing embodiments, any ion may be employed as long as it can eventually modify the organic SOG films 6 and 13. Typically, boron ion, nitrogen ion or phosphorus ion can be suitably employed as well as argon ion. Boron ion is most preferable. Further, the following ions are expected to exhibit sufficient effects:

(1) Inert gas ions other than argon: helium ion, neon ion, krypton ion, xenon ion and radon ion. Since the inert gas does not react with the organic SOG film 6(13), there is absolutely no fear of bringing about adverse effects by the ion implantation;

(2) Simple substance ions of Group IIIb, IVb, Vb, VIb, and VIIb elements excluding boron and nitrogen and ions of compounds containing such elements: particularly, ions of elements including oxygen, aluminum, sulfur, chlorine, gallium, germanium, arsenic, selenium. bromine, antimony, iodine, indium, tin, tellurium, lead and bismuth and compound ions containing such elements. Of these ions, although the metallic element ions reduce the dielectric constant of the organic SOG film 6(13) after the ion implantation.

(3) Ions of Group IVa and Va elements and ions of compounds containing such elements: particularly, ions of elements including titanium, vanadium, niobium, hafnium and tantalum and compound ions containing such elements. Since oxides of Group IVa and Va elements have high dielectric constants, the organic SOG film 6(13) after the ion implantation comes to have a high dielectric constant. However, they present no practical problem except for the cases where interlayer insulating films having particularly high dielectric constants are required; and

(4) Combinations of the ions described in (1) to (3): In this case, superior effects can be obtained by the synergistic effects brought about by the respective ions.

While an ion is implanted to the organic SOG film 6(13) in the foregoing embodiments, the material to be implanted to the film 6 may not be limited to ions but may be atoms, molecules or particles, and they are all referred to as impurities in the present invention.

What is claimed is:

1. A method of fabricating a semiconductor device, comprising the steps of:
forming wirings on a semiconductor substrate;
forming an organic SOG (Spin-on-Glass) film that is at least a part of a passivation film for insulating and protecting the wirings; and
introducing at least one impurity selected from the group consisting of argon, boron, nitrogen, and phosphorus into at least the organic SOG film.

2. The method according to claim 1, further comprising the step of forming a film having a hygroscopicity lower than the organic SOG film on at least one of an upper side and a lower side of organic SOG film.

3. The method according to claim 2, wherein the film having the lower hygroscopicity contains at least one material selected the group consisting of silicon nitride film, silicon oxide film and silicon oxynitride film.

4. The method according to claim 1, wherein said introducing at least one impurity includes introducing at least one impurity into the organic SOG film by applying a kinetic energy to the at least one impurity using a method including ion implantation.
